(19) United States
(12) Patent Application Publication
(10) Pub. No.: US 2026/0093871 A1
(43) Pub. Date: Apr. 2, 2026

(54) STATE DETECTION DEVICE, STATE DETECTION METHOD, AND COMPUTER PROGRAM

(71) Applicant: SHINWA CONTROLS CO., LTD, Kawasaki-Shi (JP)

(72) Inventor: Hiroyuki KAWAZATO, Kawasaki-Shi (JP)

(73) Assignee: SHINWA CONTROLS CO., LTD, Kawasaki-Shi (JP)

(21) Appl. No.: 19/123,139

(22) PCT Filed: Nov. 10, 2023
(86) PCT No.: PCT/JP2023/040499

§ 371 Date: Apr. 22, 2025

(30) Foreign Application Priority Data
Nov. 10, 2022 (JP) 2022-180399

(51) Int. Cl. G06F 30/27

(52) U.S. Cl. CPC G06F 30/27

(57) ABSTRACT

A state detection device including a numerical value acquisition unit that acquires an actual opening degree and a target opening degree of a flow rate control valve as specific numerical values continuously detected and/or specified, and a prediction value specification unit that specifies, based on the plurality of specific numerical values (actual opening degree and target opening degree) acquired by the numerical value acquisition unit, a prediction value of the actual opening degree that is a specific numerical value next to the plurality of specific numerical values. Then, when a difference between the prediction value corresponding to the actual opening degree and the actual opening degree corresponding to the prediction value is a predetermined value or more, the prediction value specification unit replaces the prediction value with the actual opening degree corresponding to the prediction value, and specifies the next prediction value and the subsequent prediction value.

### TECHNICAL FIELD

Embodiments of the present invention relate to a state detection device, a state detection method, and a computer program.

### BACKGROUND ART

Various techniques related to state detection have been proposed so far.

For example, a temperature control apparatus that controls a temperature of a temperature control target with a fluid, such as a refrigeration apparatus or a chiller apparatus, may be provided with an electric valve that controls a flow of the fluid. In such a valve, an operation abnormality may occur due to generation of rust or wear, clogging of foreign matters, or the like.

The detection of the operation abnormality that can occur in the valve as described above has been conventionally performed. Specifically, for example, a method of detecting the operation abnormality of the valve based on an abnormal increase in the value of a current supplied to the valve has been adopted in some cases. It can be said that this method is basically a simple method because the occurrence of the abnormality is detected by comparing the value of the current supplied to the valve with a predetermined threshold.

On the other hand, in particular, a technique of detecting a state by a prediction model (learned model) based on machine learning has become widespread in recent years. Such a technique can be said to be effective for detecting a sign of an abnormality. That is, according to such a prediction model, it is possible to expect avoidance of occurrence of a serious abnormality by detecting a sign before an apparent abnormality actually occurs.

The above-described prediction model is, for example, an algorithm that predicts a future actual measured value using an actual measured value as an input value. When an abnormality is determined using such a prediction model, the occurrence of the abnormality may be estimated based on the degree of deviation between a prediction value and an actual measured value.

However, in the prediction model that performs prediction using an actual measured value as an input value, for example, an actual measured value when an abnormality is occurring or when an abnormality has occurred is used as an input value, and thus there is a possibility that the degree of deviation between the actual measured value and the prediction value for estimating the occurrence of the abnormality cannot be accurately evaluated.

Specifically, for example, the prediction value specified using the actual measured value when the abnormality has occurred may be a value close to an actual measured value indicating the next abnormality corresponding to the prediction value. In this case, there is a possibility that the occurrence of the abnormality to be estimated cannot be accurately estimated. On the other hand, also when a prediction value is specified from a prediction value, the prediction value may greatly deviate from an actual measured value with the lapse of time. In this case, there is a possibility that the occurrence of an abnormality that should not be estimated is estimated.

In view of the above circumstances, an object of the present invention is to provide a state detection device, a state detection method, and a computer program capable of accurately specifying a prediction value for determining a state such as an abnormality and thus accurately detecting the state.

An embodiment of the present invention relates to the following aspects “1” to “10”.
[1] A state detection device including: a numerical value acquisition unit that acquires a specific numerical value continuously detected and/or specified; and a prediction value specification unit that specifies, based on a plurality of the specific numerical values acquired by the numerical value acquisition unit, a prediction value of a specific numerical value next to the plurality of specific numerical values, the state detection device detecting a state based on the specific numerical value acquired by the numerical value acquisition unit and the prediction value specified by the prediction value specification unit, in which
   the prediction value specification unit
   replaces, when a difference between the specified prediction value and the specific numerical value corresponding to the prediction value is a predetermined value or more, the prediction value with the specific numerical value corresponding to the prediction value, and specifies a next prediction value and a subsequent prediction value, and
   does not replace, when the difference between the specified prediction value and the specific numerical value corresponding to the prediction value is less than the predetermined value, the prediction value with the specific numerical value corresponding to the prediction value, and specifies the next prediction value and the subsequent prediction value using the specific numerical value.
[1] The state detection device according to [1], further including an error evaluation unit that specifies a ratio of a number of times the difference between the prediction value specified by the prediction value specification unit and the specific numerical value corresponding to the prediction value is less than the predetermined value in a plurality of predictions performed by the prediction value specification unit within a predetermined time; and
   an abnormality notification unit that notifies an abnormality when the ratio specified by the error evaluation unit is less than a predetermined ratio.
[3] The state detection device according to [2], further including a setting change unit that changes the predetermined value and the predetermined ratio, in which
   the setting change unit automatically adjusts the predetermined value and the predetermined ratio in an inversely proportional relationship.
[4] The state detection device according to any one of [1] to [3], in which the numerical value acquisition unit acquires, as the specific numerical value, a command value continuously input to a machine element to operate the machine element and an evaluation value of an operation state of the machine element continuously detected, and
   the prediction value specification unit specifies, based on a plurality of the command values excluding a latest command value and a plurality of the evaluation values excluding a latest evaluation value as the specific numerical value, a prediction value corresponding to the latest evaluation value as the prediction value.
[5] The state detection device according to [4], in which the prediction value specification unit
   replaces, when a difference between the prediction value corresponding to the latest evaluation value and the latest evaluation value that is a specific numerical value corresponding to the prediction value is the predetermined value or more, the prediction value with the latest evaluation value corresponding to the prediction value, and specifies a next prediction value after the numerical value acquisition unit acquires the command value and the evaluation value to be next treated as a latest command value and a latest evaluation value, and
   does not replace, when the difference between the prediction value corresponding to the latest evaluation value and the latest evaluation value that is the specific numerical value corresponding to the prediction value is less than the predetermined value, the prediction value with the latest evaluation value corresponding to the prediction value, and specifies the next prediction value using the evaluation value after the numerical value acquisition unit acquires the command value and the evaluation value to be next treated as the latest command value and the latest evaluation value.
[6] The state detection device according to [4] or [5], in which the prediction value specification unit performs prediction with a learned model that has learned, as a normal state, a training command value continuously input to the machine element to operate the machine element in the normal state and a training evaluation value corresponding to the operation state of the machine element operating according to the training command value and predicts a normal value corresponding to a next training evaluation value based on a plurality of variables corresponding to the training command value and a plurality of variables corresponding to the training evaluation value, and
   the prediction value specification unit specifies a prediction value corresponding to the evaluation value using, as variables, a plurality of the command values and a plurality of the evaluation values as the specific numerical value in the learned model.
[7] A state detection method including: a numerical value acquisition step of acquiring a specific numerical value continuously detected and/or specified; and a prediction value specification step of specifying, based on a plurality of the specific numerical values acquired in the numerical value acquisition step, a prediction value of a specific numerical value next to the plurality of specific numerical values, the state detection method being for detecting a state based on the specific numerical value acquired in the numerical value acquisition step and the prediction value specified in the prediction value specification step, in which
   in the prediction value specification step,
   when a difference between the specified prediction value and the specific numerical value corresponding to the prediction value is a predetermined value or more, the prediction value is replaced with the specific numerical value corresponding to the prediction value, and a next prediction value and a subsequent prediction value are specified, and
   when the difference between the specified prediction value and the specific numerical value corresponding to the prediction value is less than the predetermined value, the prediction value is not replaced with the specific numerical value corresponding to the prediction value, and the next prediction value and the subsequent prediction value are specified using the specific numerical value.
[8] The state detection method according to [7], further including a learned model preparation step of preparing a learned model for learning, as a normal state, a training command value continuously input to a machine element to operate the machine element in the normal state and a training evaluation value corresponding to an operation state of the machine element operating according to the training command value, and for predicting a normal value corresponding to a next training evaluation value based on a plurality of variables corresponding to the training command value and a plurality of variables corresponding to the training evaluation value, in which
   in the numerical value acquisition step, a command value continuously input to the machine element to operate the machine element and an evaluation value of the operation state of the machine element continuously detected are acquired as the specific numerical value, and
   in the prediction value specification step, a prediction value corresponding to the evaluation value is specified using, as variables, a plurality of the command values and a plurality of the evaluation values as the specific numerical value in the learned model.
[9] A state detection device that detects a state of a valve that changes an opening degree according to an input command signal, the state detection device including:
   a numerical value acquisition unit that acquires, as a specific numerical value continuously detected and/or specified, information on an actual opening degree of the valve; and
   a prediction value specification unit that specifies, based on the information on a plurality of the actual opening degrees acquired by the numerical value acquisition unit, a prediction value of an actual opening degree next to the plurality of actual opening degrees, in which
   the state is detected based on the information on the actual opening degree of the valve acquired by the numerical value acquisition unit and the prediction value of the actual opening degree specified by the prediction value specification unit,
   the prediction value specification unit
   replaces, when a difference between the specified prediction value and the actual opening degree corresponding to the prediction value is a predetermined value or more, the prediction value with the actual opening degree corresponding to the prediction value, and specifies a next prediction value and a subsequent prediction value, and
   does not replace, when the difference between the specified prediction value and the actual opening degree corresponding to the prediction value is less than the predetermined value, the prediction value with the actual opening degree corresponding to the prediction value, and specifies the next prediction value and the subsequent prediction value using the actual opening degree.
[10] A computer program for causing a computer to execute: a numerical value acquisition step of acquiring a specific numerical value continuously detected and/or specified; and a prediction value specification step of specifying, based on a plurality of the specific numerical values acquired in the numerical value acquisition step, a prediction value of a specific numerical value next to the plurality of specific numerical values, the computer program being for detecting a state based on the specific numerical value acquired in the numerical value acquisition step and the prediction value specified in the prediction value specification step,
   in the prediction value specification step,
   when a difference between the specified prediction value and the specific numerical value corresponding to the prediction value is a predetermined value or more, the prediction value is replaced with the specific numerical value corresponding to the prediction value, and a next prediction value and a subsequent prediction value are specified, and
   when the difference between the specified prediction value and the specific numerical value corresponding to the prediction value is less than the predetermined value, the prediction value is not replaced with the specific numerical value corresponding to the prediction value, and the next prediction value and the subsequent prediction value are specified using the specific numerical value.

According to the present invention, the prediction value for determining the state can be accurately specified and thus the state can be accurately detected.

### BRIEF DESCRIPTION OF DRAWINGS

FIG. 1 is a diagram schematically illustrating a state detection device according to an embodiment and a temperature control apparatus to which the state detection device is applied.

FIG. 2 is a block diagram illustrating a functional configuration of the state detection device of FIG. 1.

FIG. 3 is a flowchart illustrating an example of a prediction operation of the state detection device of FIG. 1.

FIG. 4 is a flowchart illustrating an example of a state detection operation of the state detection device of FIG. 1.

FIG. 5 is a diagram conceptually illustrating the prediction operation of FIG. 3.

FIG. 6 is a diagram illustrating a procedure for determining a predetermined value for evaluating a difference between a prediction value calculated during the operations illustrated in FIGS. 3 and 4 and a specific numerical value that is an actual measured value.

### BEST MODE FOR CARRYING OUT THE INVENTION

Hereinafter, an embodiment will be described.

### Configuration of State Detection Device and Temperature Control Apparatus

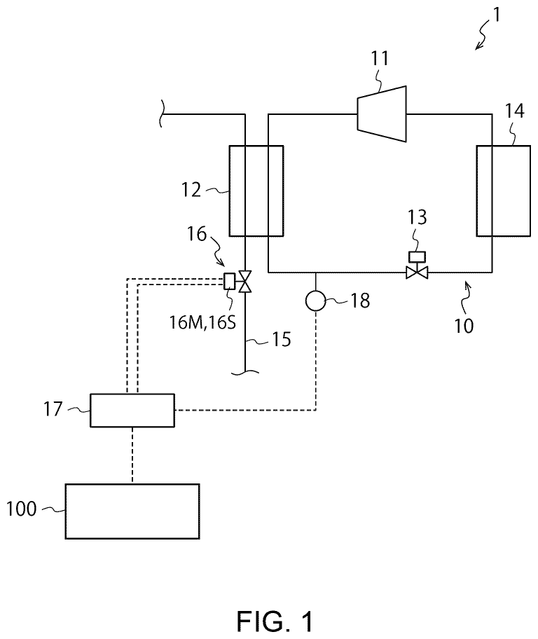

FIG. 1 is a diagram schematically illustrating a state detection device 100 according to the embodiment and a refrigeration apparatus 1 as a temperature control apparatus to which the state detection device 100 is applied.

The refrigeration apparatus 1 includes a refrigeration circuit 10 including a compressor 11, a condenser 12, an expansion valve 13, and an evaporator 14. In the refrigeration circuit 10, the compressor 11, the condenser 12, the expansion valve 13, and the evaporator 14 are connected by a piping member (pipe) so as to circulate a refrigerant in this order. The refrigeration apparatus 1 exchanges heat between the refrigerant flowing through the evaporator 14 and a temperature control target (not illustrated) to control the temperature of the temperature control target.

The compressor 11 compresses the refrigerant flowing out of the evaporator 14 and basically in a gaseous state, and supplies the refrigerant to the condenser 12 in a state where the temperature and pressure of the refrigerant are increased. The condenser 12 cools and condenses the refrigerant compressed by the compressor 11 with cooling water to bring the refrigerant into a high-pressure liquid state at a predetermined temperature, and supplies the refrigerant to the expansion valve 13. The expansion valve 13 expands the refrigerant from the condenser 12 to bring the refrigerant into a gas-liquid mixed phase state and allows the refrigerant to flow into the evaporator 14. The refrigerant flowing from the expansion valve 13 into the evaporator 14 decreases in temperature due to expansion. As a result, the evaporator 14 can, for example, cool the temperature control target by exchanging heat between the refrigerant and the temperature control target.

A cooling water flow path 15 is connected to the condenser 12. The cooling water flow path 15 is provided with a flow rate control valve 16. The cooling water flow path 15 is a flow path that allows the cooling water to flow into the condenser 12 and allows the cooling water flowing out of the condenser 12 to flow. The flow rate control valve 16 adjusts a flow rate of cooling water flowing into the condenser 12 from the cooling water flow path 15. In the present embodiment, the flow rate control valve 16 is provided in a portion of the cooling water flow path 15 on the upstream side of the condenser 12, but may be provided on the downstream side of the condenser 12.

The flow rate control valve 16 is a proportional valve that adjusts the flow rate of the cooling water flowing into the condenser 12 by adjusting an opening degree. The flow rate control valve 16 in the present embodiment includes a motor 16M, and the opening degree of the flow rate control valve 16 is adjusted by the motor 16M adjusting the position of a valve body. In addition, the flow rate control valve 16 includes an opening degree detection unit 16S, and the opening degree of the valve can be specified by the opening degree detection unit 16S. The opening degree detection unit 16S may include an encoder capable of recognizing a rotational change amount of a rotation shaft of the motor 16M from a reference position, or may specify the opening degree of the valve based on the rotational change amount detected by the encoder. Note that the motor 16M in the flow rate control valve 16 is a stepping motor in the present embodiment, but may be a DC servomotor or an AC servomotor. In addition, the flow rate control valve 16 may be a proportional electromagnetic valve.

Specifically, the motor 16M of the flow rate control valve 16 is electrically connected to a controller 17, and the opening degree of the flow rate control valve 16 is controlled by the controller 17. In the present embodiment, a pressure sensor 18 that detects the pressure of the refrigerant flowing through a portion on the downstream side of the condenser 12 and the upstream side of the expansion valve 13 in the refrigeration circuit 10 is provided. Information on the pressure detected by the pressure sensor 18 is provided to the controller 17. Then, the controller 17 in the present embodiment controls the flow rate control valve 16 such that the pressure detected by the pressure sensor 18 matches a predetermined target pressure.

The controller 17 controls the flow rate control valve 16 such that the pressure detected by the pressure sensor 18 matches the target pressure by feedback control based on a difference between the pressure detected by the pressure sensor 18 and the target pressure. The controller 17 controls the flow rate control valve 16 by PID control, but control may be performed by PI control, PD control, or other methods. In addition, by providing a temperature sensor instead of the pressure sensor 18, the controller 17 may control the flow rate control valve 16 such that the temperature detected by the temperature sensor matches the target temperature.

The controller 17 calculates a target opening degree (a value in a range of 0 to 100%) as a command value, and outputs the target opening degree to the flow rate control valve 16. In the present embodiment, since the controller 17 is electrically connected to the motor 16M that is a stepping motor, the target opening degree output by the controller 17 is actually converted into a set of pulse signals and output. Then, the set of pulse signals corresponding to the target opening degree is input to the flow rate control valve 16 as a command signal. Then, the motor 16M changes the rotational position according to the output pulse signal to adjust the opening degree of the flow rate control valve 16.

The controller 17 calculates a target opening degree at a predetermined cycle, and then generates a set of pulse signals corresponding to the target opening degree. The controller 17 calculates the target opening degree by increasing or decreasing the target opening degree as a command value according to the difference between the pressure detected by the pressure sensor 18 and the target pressure. The set of pulse signals can also be said to be a signal waveform for generating one or more pulse signals in a time width corresponding to the predetermined cycle. The number of pulse signals included in the set of generated pulse signals increases or decreases according to the difference between the pressure detected by the pressure sensor 18 and the target pressure.

More specifically, as the difference is larger, the controller 17 includes more pulse signals in the set of pulse signals. In this case, as the number of pulse signals included in the set of pulse signals received by the motor 16M increases, the rate of change in the opening degree of the flow rate control valve 16 toward the target opening degree can be increased. In the present embodiment, when receiving the set of pulse signals from the controller 17, the flow rate control valve 16 attempts to operate to the target opening degree in a time width corresponding to the set. However, the control mode of the flow rate control valve 16 by the controller 17 is not limited to the above-described example, and may be another method.

The controller 17 may be configured by a computer including a CPU and a ROM, a microcomputer, or the like. In this case, the controller 17 performs various processes according to a program stored in the ROM. Note that the controller 17 may be another processor or an electric circuit (for example, a field programmable gate alley (FPGA) or the like).

The state detection device 100 is electrically connected to the controller 17. Then, the state detection device 100 is provided with a command value (“target opening degree” in this example) output from the controller 17 to the motor 16M and information on the current opening degree of the flow rate control valve 16 from the controller 17. As described above, in the present embodiment, the controller 17 calculates the target opening degree at the predetermined cycle. Every time the controller 17 calculates the target opening degree, the state detection device 100 in the present embodiment is provided with the information on the target opening degree and information on an actual opening degree of the flow rate control valve 16 at a time point when the information on the target opening degree is provided.

Then, the state detection device 100 predicts, based on the information on a plurality of the target opening degrees and the information on a plurality of the actual opening degrees as specific numerical values continuously detected and/or specified, an actual opening degree next to the information on the plurality of actual opening degrees. In addition, the state detection device 100 detects the state of the flow rate control valve 16, specifically, an abnormality based on the predicted opening degree of the flow rate control valve 16 and the corresponding actual opening degree of the flow rate control valve 16.

The state detection device 100 may be configured by a computer including a CPU and a ROM, a microcomputer, or the like. In this case, the state detection device 100 performs various processes according to a program stored in the ROM. Note that the controller 17 may be another processor or an electric circuit (for example, a field programmable gate alley (FPGA) or the like). Although the controller 17 and the state detection device 100 are separate devices in the present embodiment, they may be integrated. Hereinafter, the state detection device 100 will be described.

### Functional Configuration of State Detection Device

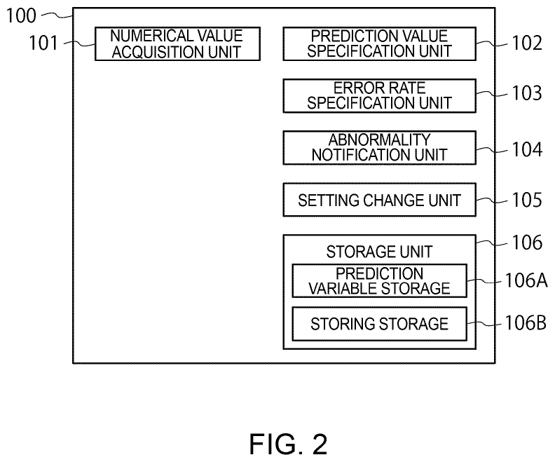

FIG. 2 is a block diagram illustrating a functional configuration of the state detection device 100. The state detection device 100 includes a numerical value acquisition unit 101, a prediction value specification unit 102, an error evaluation unit 103, an abnormality notification unit 104, a setting change unit 105, and a storage unit 106. When the state detection device 100 is configured by, for example, a computer, the numerical value acquisition unit 101, the prediction value specification unit 102, the error evaluation unit 103, the abnormality notification unit 104, and the setting change unit 105 can be realized by executing the program stored in the ROM. On the other hand, the storage unit 106 may be configured by a part of the ROM.

The numerical value acquisition unit 101 acquires, as specific numerical values continuously detected and/or specified, information on the target opening degree of the flow rate control valve 16 calculated by the controller 17 and information on the actual opening degree of the flow rate control valve 16 detected by the opening degree detection unit 16S.

Here, the information on the target opening degree corresponds to a command value continuously input to the flow rate control valve 16 to operate the flow rate control valve 16 that is a mechanical element. The information on the actual opening degree corresponds to a continuously detected evaluation value of an operation state of the flow rate control valve 16. The information on the target opening degree and the information on the actual opening degree acquired by the numerical value acquisition unit 101 are sequentially held in a prediction variable storage 106A to be described later set in the storage unit 106.

The prediction value specification unit 102 is a unit that specifies, based on the information on the plurality of target opening degrees and the information on the plurality of actual opening degrees acquired by the numerical value acquisition unit 101 and held in the prediction variable storage 106A as described above, a prediction value of an actual opening degree next to the plurality of actual opening degrees. Specifically, the prediction value specification unit 102 in the present embodiment specifies, based on information on a plurality of target opening degrees excluding information on the latest target opening degree and information on a plurality of actual opening degrees excluding information on the latest actual opening degree in the prediction variable storage 106A, a prediction value corresponding to the information on the latest actual opening degree. In the present embodiment, when the number of pieces of the information on the plurality of target opening degrees used by the prediction value specification unit 102 is n, the number of pieces of the information on the plurality of actual opening degrees is also n. n is an integer and may be 4 to 10.

In addition, the prediction value specification unit 102 in the present embodiment is configured such that after the prediction value is specified as described above, information on an actual opening degree used for the next prediction is replaced with the prediction value as necessary based on a difference between the prediction value and the latest actual opening degree corresponding to the prediction value.

Specifically, when a difference between a prediction value corresponding to the latest actual opening degree and the latest actual opening degree that is an actual measured value corresponding to the prediction value is a predetermined value or more, the prediction value specification unit 102 replaces the prediction value with the latest actual opening degree corresponding to the prediction value, and specifies the next prediction value and the subsequent prediction value. On the other hand, when the difference between the prediction value corresponding to the latest actual opening degree and the latest implemented opening degree that is an actual measured value corresponding to the prediction value is less than the predetermined value, the prediction value specification unit 102 does not replace the prediction value with the latest actual opening degree corresponding to the prediction value, and specifies the next prediction value and the subsequent prediction value using the actual opening degree. The prediction value replaced with respect to the actual opening degree is maintained in the subsequent prediction.

As will be described later, the state detection device 100 detects an abnormality based on detecting a state in which a difference between a prediction value of the opening degree and the corresponding actual measured value of the opening degree is large. Here, when the prediction value is specified based on an actual measured value that is not normal, the prediction value does not indicate a normal behavior in some cases, and there is a possibility that an abnormality cannot be accurately detected. Therefore, it is desirable that the prediction value indicates a normal behavior. Therefore, as described above, the prediction value specification unit 102 replaces the prediction value with the actual measured value corresponding to the prediction value as necessary, and performs the subsequent prediction.

The prediction value specification unit 102 as described above is configured to perform prediction using a learned model as an example in the present embodiment. This learned model has learned, as a normal state (normal data set), a training command value (target opening degree) continuously input to the flow rate control valve 16 to operate the flow rate control valve 16 in a normal state and a training evaluation value (actual opening degree) corresponding to an operation state of a machine element operating according to the training command value.

Specifically, in the above-described learned model, the training command value and the training evaluation value are sequentially input, and machine learning is performed using, as explanatory variables, a plurality of the training command values excluding the latest training command value and a plurality of the training evaluation values excluding the latest training evaluation value among the plurality of training evaluation values and using the latest training evaluation value as a correct answer label. Then, the learned model is constructed to predict a normal value corresponding to the next training evaluation value based on a plurality of variables corresponding to the training command values and a plurality of variables corresponding to the training evaluation values.

As a result, the learned model used in the present embodiment is constructed to specify, as a value corresponding to the correct answer label, a prediction value corresponding to an actual opening degree using, as explanatory variables, a plurality of target opening degrees as a plurality of command values and a plurality of actual opening degrees as a plurality of evaluation values acquired by the numerical value acquisition unit 101.

As an example, the learned model used by the prediction value specification unit 102 as described above is constructed by machine learning based on light gradient boosting machine (LightGBM). However, the learned model used by the prediction value specification unit 102 is not particularly limited, and may be constructed by other machine learning such as a neural network or an SVM. In addition, the prediction value specification unit 102 may specify a prediction value by a method such as a regression method.

In the present embodiment, the prediction value of the actual opening degree specified by the prediction value specification unit 102 and the difference between the prediction value and the actual opening degree corresponding to the prediction value are sequentially held in a storing storage 106B to be described later set in the storage unit 106. Such information may be used when the learned model used by the prediction value specification unit 102 is improved thereafter.

In addition, in the present embodiment, when or after the prediction value of the actual opening degree specified by the prediction value specification unit 102 and the difference between the prediction value and the actual opening degree corresponding to the prediction value are held in the storing storage 106B, in a case where the difference is less than the predetermined value, a flag (for example, “1”) indicating the case (in other words, normality) is held in association with the difference while in a case where the difference is the predetermined value or more, a flag (for example, “0”) indicating the case (in other words, non-normality) is held in association with the difference.

The error evaluation unit 103 is a unit that specifies the ratio of the number of times the difference between the prediction value of the actual opening degree specified by the prediction value specification unit 102 and the actual opening degree corresponding to the prediction value is less than the predetermined value in a plurality of predictions performed by the prediction value specification unit 102 within a predetermined time. Specifically, the error evaluation unit 103 specifies the ratio of the number of the differences associated with the flag (for example, “1”) indicating less than the predetermined value in information on a predetermined number (for example, 3600) of the differences held in the storing storage 106B as described above. As a result, the error evaluation unit 103 specifies the ratio of the number of times the difference between the prediction value and the actual measured value is less than the predetermined value in the plurality of predictions performed by the prediction value specification unit 102 within the predetermined time.

Then, the error evaluation unit 103 determines that an abnormality has occurred when the ratio of the number of times the difference between the prediction value and the actual opening degree is less than the predetermined value in the plurality of predictions performed by the prediction value specification unit 102 within the predetermined time is less than a predetermined ratio.

When determining that an abnormality has occurred, the error evaluation unit 103 provides alarm information to the abnormality notification unit 104. The abnormality notification unit 104 notifies the abnormality when receiving the alarm information from the error evaluation unit 103. The abnormality notification may be performed by, for example, a warning display on a display (not illustrated) or may be performed by generation of an alarm sound.

The setting change unit 105 is a unit that changes the predetermined value used by the prediction value specification unit 102 to evaluate the difference and the predetermined ratio used by the prediction value specification unit 102 to determine whether or not to notify an abnormality. The setting change unit 105 in the present embodiment changes the predetermined value and the predetermined ratio in conjunction with each other according to a user's operation. Specifically, the setting change unit 105 automatically adjusts the predetermined value and the predetermined ratio in an inversely proportional relationship.

In the present embodiment, the prediction value of the actual opening degree specified by the prediction value specification unit 102 and the actual opening degree corresponding to the prediction value are specified by any values between fully closed 0% and fully opened 100%. Here, it is assumed that the predetermined value is set to 1% in units of the opening degree of the flow rate control valve 16, and the predetermined ratio for determining whether or not to notify an abnormality is set to 60%. From this state, for example, when the predetermined value is increased to 2% by using the setting change unit 105, the predetermined ratio is automatically lowered to, for example, 40%.

The combination of the predetermined value and the predetermined ratio determined by the setting change unit 105 is specified in advance as a combination of optimum values with which an abnormality can be detected with high reliability based on a case where an abnormality has actually occurred. According to such a setting change unit 105, it is possible to flexibly perform desirable state detection according to situations. However, the predetermined value and the predetermined ratio may be arbitrarily set.

The storage unit 106 sets the prediction variable storage 106A and the storing storage 106B described above in a part of a data holding portion and holds each piece of storage information. Here, when the number of pieces of information on the plurality of target opening degrees used by the prediction value specification unit 102 is set to n and the number of pieces of information on the plurality of actual opening degrees is also set to n, the prediction variable storage 106A may be configured to have n+1 storage areas for the target opening degrees and n+1 storage areas for the plurality of actual opening degrees.

In the prediction variable storage 106A as described above, the information on the target opening degree first acquired by the numerical value acquisition unit 101 is held in the n+1th storage area for the target opening degree, and the information on the actual opening degree first acquired by the numerical value acquisition unit 101 is held in the n+1th storage area for the actual opening degree. Then, before the information on the target opening degree is acquired next, the information on the target opening degree held in the n+1th storage area is moved to the nth storage area, and information on a new target opening degree is held in the n+1th storage area. The information on the actual opening degree is held similarly to the information on the target opening degree. Then, when the next information is acquired after the first to n+1th storage areas for the target opening degree are filled with the information on the target opening degree, the information in the first storage area is discharged. The same discharge process is performed for the actual opening degree. Note that the configuration of the prediction variable storage 106A is not particularly limited, and at least the prediction value specification unit 102 may have a storage area capable of holding information used for prediction.

The storage unit 106 as described above may be configured by a main storage device or an auxiliary storage device. In addition, the storage unit 106 holds various operation programs.

### Prediction Operation

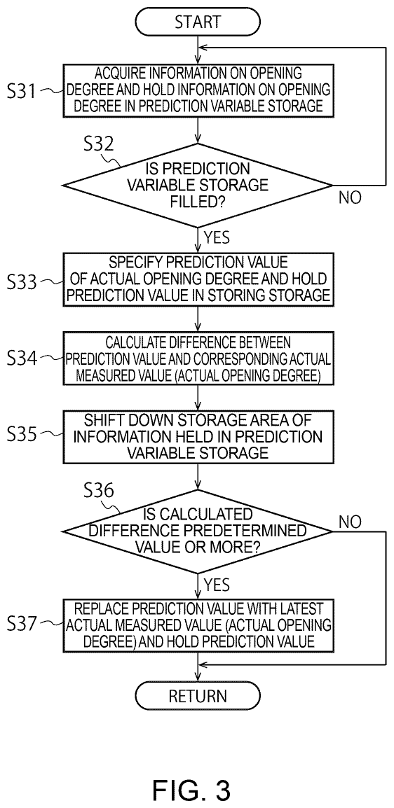

Next, an example of a prediction operation of the state detection device 100 will be described with reference to a flowchart illustrated in FIG. 3. The prediction operation of the state detection device 100 starts when the operation of the refrigeration apparatus 1 starts.

First, in step S31, the state detection device 100 acquires, from the controller 17, information on the target opening degree of the flow rate control valve 16 calculated by the controller 17 and information on the actual opening degree of the flow rate control valve 16 detected by the opening degree detection unit 16S. The information is acquired by the numerical value acquisition unit 101. Then, the information on the target opening degree and the information on the actual opening degree acquired by the numerical value acquisition unit 101 are sequentially held in the prediction variable storage 106A.

Next, in step S32, the state detection device 100 determines whether or not the prediction variable storage 106A is filled with the information on the target opening degree and the information on the actual opening degree. Specifically, the state detection device 100 determines whether or not the first to n+1th storage areas for the target opening degree are satisfied with the information on the target opening degree and the first to n+1th storage areas for the actual opening degree are satisfied with the information on the actual opening degree in the prediction variable storage 106A.

Then, when it is not determined in step S32 that the prediction variable storage 106A is filled, the acquisition of the information in step S31 is repeated. On the other hand, when it is determined in step S32 that the prediction variable storage 106A is filled, the state detection device 100 specifies a prediction value of the information on the actual opening degree with the prediction value specification unit 102 in step S33.

In step S33, the prediction value specification unit 102 specifies a prediction value corresponding to information on the latest actual opening degree based on the information on the plurality of target opening degrees excluding the information on the latest target opening degree and the information on the plurality of actual opening degrees excluding the information on the latest actual opening degree. That is, the prediction value specification unit 102 specifies a prediction value of the actual opening degree n+1th held based on information on the first to nth target opening degrees among the information on the target opening degrees held in the first to n+1th storage areas for the target opening degree in the prediction variable storage 106A and information on the first to nth target opening degrees among the information on the actual opening degrees held in the first to n+1th storage areas for the actual opening degree in the prediction variable storage 106A, and holds the prediction value in the storing storage 106B.

Thereafter, in step 34, a difference between the prediction value specified in step S33 by the prediction value specification unit 102 and the actual opening degree that is an actual measured value corresponding to the prediction value is calculated. That is, a difference between the prediction value specified in step S33 and the latest actual opening degree held in the n+1th storage area in the prediction variable storage 106A is calculated. Then, this difference is held in the storing storage 106B.

Next, in step S35, the information held in the first storage area on the target opening degree and the actual opening degree in the prediction variable storage 106A is discharged, the other information is moved to the storage area shifted down by one from the current storage area, and the n+1th storage area is made free.

Thereafter, in step S36, the prediction value specification unit 102 determines whether or not the difference calculated in step S34 is the predetermined value or more. Then, when the difference is the predetermined value or more in step S36 (YES in S36), the prediction value specification unit 102 replaces, in step S37, the prediction value corresponding to the latest actual opening degree and specified in step S33 with the latest actual opening degree corresponding to the prediction value and currently held in the nth storage area in the prediction variable storage 106A, and holds the prediction value. Then, after the process of step S37, the process returns to step S31, and information on the next target opening degree and information on the actual opening degree are acquired.

On the other hand, when the difference is less than the predetermined value in step 36 (NO in S36), the prediction value specification unit 102 does not replace the prediction value corresponding to the latest actual opening degree and specified in step S33 with the latest actual opening degree corresponding to the prediction value and currently held in the nth storage area in the prediction variable storage 106A. That is, the information on the actual opening degree that is an actual measured value is kept held in the prediction variable storage 106A. Thereafter, the process returns to step S31, and information on the next target opening degree and information on the actual opening degree are acquired.

### State Detection Operation

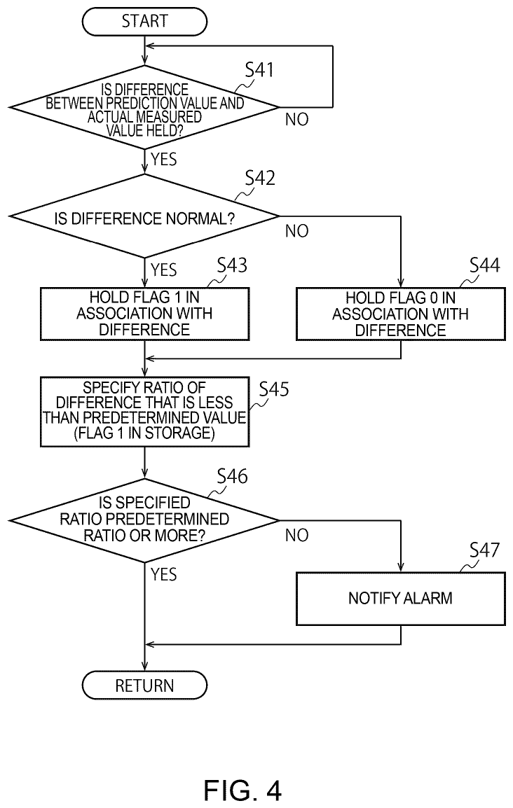

Hereinafter, an example of a state detection operation of the state detection device 100 will be described with reference to FIG. 4. The state detection operation of the state detection device 100 starts when the operation of the refrigeration apparatus 1 starts, and is performed in parallel with the prediction operation described above.

In the prediction operation as described above, the difference between the prediction value specified in step S33 by the prediction value specification unit 102 and the actual opening degree that is an actual measured value corresponding to the prediction value is calculated and held in the storing storage 106B (step S34). In the state detection operation, first in step S41, the state detection device 100 monitors whether or not the difference calculated in step S34 is held in the storing storage 106B. Then, monitoring is continued until the holding of the difference is confirmed.

Then, when the difference is held in the storing storage 106B, the state detection device 100 determines in step S42 whether or not the difference is normal based on whether or not the difference is the predetermined value or more used in the determination of step S36.

Then, when the difference is less than the predetermined value in the determination of step S42 (YES in S42), a flag indicating 1 (flag indicating normality) is associated with the difference as an example in the operation example in step S43, and the flag indicating 1 is held in the storing storage 106B together with the difference. On the other hand, when the difference is the predetermined value or more in the determination in step S42 (NO in S42), a flag indicating 0 (flag indicating non-normality) is associated with the difference as an example in the operation example in step S44, and the flag indicating 0 is held in the storing storage 106B together with the difference.

Then, in step S45 after the processes of steps S43 and S44, the error evaluation unit 103 specifies the ratio of the number of times the difference between the prediction value of the actual opening degree specified by the prediction value specification unit 102 and the actual opening degree corresponding to the prediction value is less than the predetermined value (normal) in the plurality of predictions performed by the prediction value specification unit 102 within the predetermined time. Specifically, the error evaluation unit 103 specifies the ratio of the number of the differences associated with the flag “1” indicating less than the predetermined value in information on the predetermined number (for example, 3600) of the differences held in the storing storage 106B. As a result, it is possible to specify the ratio of the number of times the difference between the prediction value and the actual opening degree is less than the predetermined value in the plurality of predictions performed by the prediction value specification unit 102 within the predetermined time.

Then, in step S46, the error evaluation unit 103 determines whether or not the ratio specified in step S45 is the predetermined ratio or more, in other words, less than the predetermined ratio. Then, when the ratio specified in step S45 is the predetermined ratio or more (YES in S46), it is determined that no abnormality has occurred, and the processes from step S41 are repeated. On the other hand, when the ratio specified in step S45 is less than the predetermined ratio (NO in S46), it is determined that an abnormality has occurred, and the abnormality notification unit 104 notifies an alarm in step S47. Thereafter, the processes from step S41 are repeated.

Note that in the present embodiment, it is determined that the abnormality has occurred when the ratio of the state (flag of 1) indicating normality is less than the predetermined ratio, but it may be determined that the abnormality has occurred when the ratio of the state (flag of 0) indicating non-normality is the predetermined ratio or more.

### Example of Prediction Operation

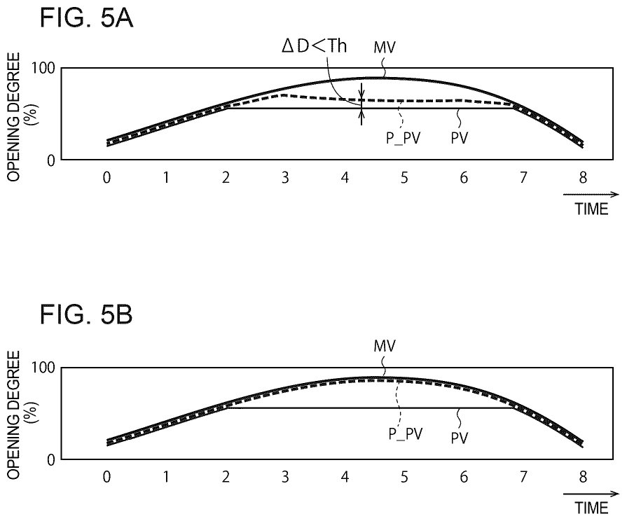

Hereinafter, an image of the above-described prediction operation will be described with reference to the drawings. FIG. 5 is a diagram conceptually illustrating the prediction operation described in FIG. 3. As described above, when the difference between the prediction value corresponding to the latest actual opening degree and the latest actual opening degree that is an actual measured value corresponding to the prediction value is the predetermined value or more, the prediction value specification unit 102 replaces the prediction value with the latest actual opening degree corresponding to the prediction value, and specifies the next prediction value and the subsequent prediction value.

In the graphs illustrated in FIGS. 5(A) and (B), the horizontal axis represents the time, and the vertical axis represents the opening degree (%) of the flow rate control valve 16. Unlike the present embodiment, FIG. 5(A) illustrates the prediction operation when the prediction value is specified using only the actual opening degree. On the other hand, FIG. 5(B) illustrates the prediction operation according to the present embodiment, and illustrates the prediction operation when the subsequent prediction value is specified using the prediction value according to situations. In FIGS. 5(A) and 5(B), an abnormality occurs after two hours from the 0 time point as a reference. Then, in FIGS. 5(A) and 5(B), the target opening degree (MV) and the actual opening degree (PV) have a common value, but the states of the opening degrees (P_PV) as the respective prediction values transition in different states.

Specifically, when the prediction value is specified using only the actual measured value unlike the present embodiment, the prediction value (P_PV) may transition at a value far from the target opening degree (MV) as illustrated in FIG. 5(A). When the flow rate control valve 16 is normal, the actual opening degree (PV) and the target opening degree (MV) have values close to each other. Therefore, the prediction value specified after two hours illustrated in FIG. 5(A) does not indicate a normal state. In the present embodiment, the prediction value is scheduled to be calculated as a normal value, and an abnormality is estimated when the degree of deviation between the prediction value and the actual measured value is large. Therefore, the prediction value specified in FIG. 5(A) is not desirable as a value for determining detection of an abnormality. For example, in FIG. 5(A), a situation may occur in which it is determined that a difference AD between the prediction value and the actual measured value after four hours is less than a predetermined value Th despite the occurrence of an abnormality and it is determined that the state is normal.

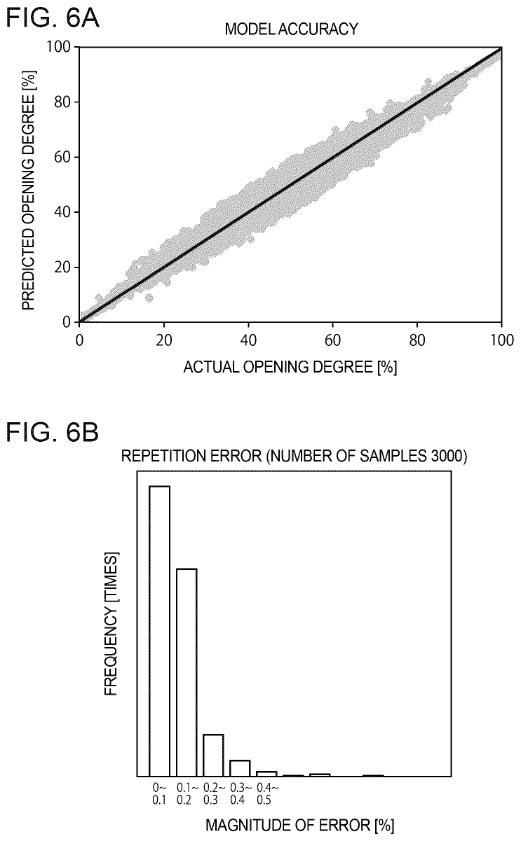

On the other hand, in the present embodiment, when the prediction value largely deviates from the actual measured value, the prediction value is used instead of the actual measured value in specifying the next prediction value. As a result, as illustrated in FIG. 6(B), the prediction value (P_PV) transitions at a value close to the target opening degree (MV). As a result, the prediction value is maintained at a value indicating a normal state, and the abnormality can be accurately estimated based on the difference between the prediction value and the actual measured value.

### Generation Procedure of Prediction Value Specification Unit

Next, an example of a generation procedure of the prediction value specification unit 102 in the present embodiment will be described. As described above, the prediction value specification unit 102 uses the learned model. This learned model is constructed to perform machine learning using, as explanatory variables, a plurality of training command values excluding the latest training command value among the plurality of training commands and a plurality of training evaluation values excluding the latest training evaluation value among the plurality of training evaluation values and using the latest training evaluation value as a correct answer label, and predict a normal value corresponding to the next training evaluation value based on a plurality of variables corresponding to the training command values and a plurality of variables corresponding to the training evaluation values.

The prediction value specification unit 102 installs the above-described learned model, and further incorporates an algorithm that evaluates the difference between the prediction value and the actual measured value with the predetermined value, replaces the actual measured value with the prediction value according to the evaluation, and performs prediction. Here, in the present embodiment, the set value is determined in consideration of model accuracy in the learned model and mechanical repetition accuracy of the flow rate control valve 16.

Specifically, before the predetermined value is determined, a test data set (target opening degree and actual opening degree) in a normal state is input to the learned model, and an error between the prediction value and the actual opening degree is evaluated, whereby MAE (average absolute error) that is an error of the opening degree is specified as the model accuracy. In addition, a command of the same target opening degree is input a plurality of times to the normal flow rate control valve 16, and an error between the actual opening degree corresponding to the command and the target opening degree is measured to specify a repetition accuracy distribution of the opening degree. Then, the maximum value of the error in the top 95% trials counted from the smallest error among the trials by the input of the plurality of commands is specified. Then, a value obtained by adding the MAE and the maximum value of the error in the top 95% trials counted from the smallest error in the repetition accuracy distribution is specified, and the above-described predetermined value is determined in a range of 0.9 to 1.1 times the value. When the predetermined value is determined based on the value considering the MAE and the repetition accuracy in this way, it is possible to accurately estimate an abnormality.

Here, FIG. 6(A) illustrates an example of a distribution of the model accuracy of the learned model. In the example of FIG. 6(A), the prediction is performed 107764 times, and the target opening degree is input over 0 to 100(%). In the example of FIG. 6(A), the MAE was calculated as 0.83%. FIG. 6(B) illustrates an example of the repetition accuracy distribution of the opening degree of the normal flow rate control valve 16. In the example of FIG. 6(B), 3000 trials are performed. Then, the maximum value of the error in the top 95% trials counted from the smallest error in the repetition accuracy distribution was 0.2%. In this case, the predetermined value for evaluating the difference between the prediction value and the actual measured value may be set to, for example, 1% based on 0.83+0.2.

The state detection device 100 according to the present embodiment described above includes the numerical value acquisition unit 101 that acquires the actual opening degree and the target opening degree of the flow rate control valve 16 as specific numerical values continuously detected and/or specified, and the prediction value specification unit 102 that specifies the prediction value of the actual measured value next to the plurality of actual measured values based on the plurality of actual opening degrees and target opening degrees acquired by the numerical value acquisition unit 101. Then, the state detection device 100 detects the state based on the actual opening degree acquired by the numerical value acquisition unit 101 and the prediction value corresponding to the actual opening degree and specified by the prediction value specification unit 102. Then, when the difference between the specified prediction value corresponding to the actual opening degree and the actual opening degree corresponding to the prediction value is the predetermined value or more, the prediction value specification unit 102 replaces the prediction value with the actual opening degree corresponding to the prediction value, and specifies the next prediction value and the subsequent prediction value. In addition, when the difference between the specified prediction value corresponding to the actual opening degree and the actual opening degree corresponding to the prediction value is less than the predetermined value, the prediction value specification unit 102 does not replace the prediction value with the actual opening degree corresponding to the prediction value, and specifies the next prediction value and the subsequent prediction value using the actual opening degree.

As a result, in the present embodiment, a prediction value for determining the state (abnormality) can be accurately specified, and the state can be accurately detected. That is, in the present embodiment, when the prediction value largely deviates from the actual measured value, the prediction value is used instead of the actual measured value in specifying the next prediction value. As a result, the prediction value is maintained at a value indicating a normal state, and the abnormality can be accurately estimated based on the difference between the prediction value and the actual measured value.

In addition, the numerical value acquisition unit 101 acquires, as specific numerical values used for prediction, a target opening degree as a command value continuously input to the flow rate control valve 16 and an actual opening degree as an evaluation value of the operation state of the flow rate control valve 16 continuously detected. Then, the prediction value specification unit 102 specifies, as a prediction value, a prediction value corresponding to the latest actual opening degree based on a plurality of target opening degrees excluding the latest target opening degree and a plurality of actual opening degrees excluding the latest actual opening degree. In this case, since the target opening degree and the actual opening degree as two variables are used, the accuracy of the prediction value can be improved. However, the prediction value specification unit 102 may predict the actual opening degree using, for example, only a plurality of actual opening degrees, in other words, using one type of variable.

In addition, in the present embodiment, the prediction value is specified to determine an abnormality, and the command value is not actively controlled based on the prediction value. In this case, by adopting the configuration in which the prediction value specification unit 102 specifies the prediction value corresponding to the latest actual opening degree based on the plurality of target opening degrees excluding the latest target opening degree and the plurality of actual opening degrees excluding the latest actual opening degree as described above, it is possible to efficiently specify the prediction value based on simple information acquisition. That is, a calculation speed in specifying the prediction value can be improved, and a processing load can be reduced.

Although the embodiment of the present invention has been described above, the present invention is not limited to the above-described embodiment, and various further modifications can be made to the above-described embodiment. For example, in the above-described embodiment, the state detection device 100 is applied to the state detection of the flow rate control valve 16 of the refrigeration apparatus 1, but may be applied to the state detection of the expansion valve 13 or the compressor 11. In addition, the state detection device 100 may be applied to a valve provided in a chiller apparatus, or may be used for other purposes.

1. A state detection device comprising: a numerical value acquisition unit that acquires a specific numerical value continuously detected and/or specified; and a prediction value specification unit that specifies, based on a plurality of the specific numerical values acquired by the numerical value acquisition unit, a prediction value of a specific numerical value next to the plurality of specific numerical values, the state detection device detecting a state based on the specific numerical value acquired by the numerical value acquisition unit and the prediction value specified by the prediction value specification unit, wherein
the prediction value specification unit
replaces, when a difference between the specified prediction value and the specific numerical value corresponding to the prediction value is a predetermined value or more, the prediction value with the specific numerical value corresponding to the prediction value, and specifies a next prediction value and a subsequent prediction value, and
does not replace, when the difference between the specified prediction value and the specific numerical value corresponding to the prediction value is less than the predetermined value, the prediction value with the specific numerical value corresponding to the prediction value, and specifies the next prediction value and the subsequent prediction value using the specific numerical value.

2. The state detection device according to claim 1, further comprising an error evaluation unit that specifies a ratio of a number of times the difference between the prediction value specified by the prediction value specification unit and the specific numerical value corresponding to the prediction value is less than the predetermined value in a plurality of predictions performed by the prediction value specification unit within a predetermined time; and
an abnormality notification unit that notifies an abnormality when the ratio specified by the error evaluation unit is less than a predetermined ratio.

3. The state detection device according to claim 2, further comprising a setting change unit that changes the predetermined value and the predetermined ratio, wherein
the setting change unit automatically adjusts the predetermined value and the predetermined ratio in an inversely proportional relationship.

4. The state detection device according to claim 1, wherein the numerical value acquisition unit acquires, as the specific numerical value, a command value continuously input to a machine element to operate the machine element and an evaluation value of an operation state of the machine element continuously detected, and
the prediction value specification unit specifies, based on a plurality of the command values excluding a latest command value and a plurality of the evaluation values excluding a latest evaluation value as the specific numerical value, a prediction value corresponding to the latest evaluation value as the prediction value.

5. The state detection device according to claim 4, wherein the prediction value specification unit
replaces, when a difference between the prediction value corresponding to the latest evaluation value and the latest evaluation value that is a specific numerical value corresponding to the prediction value is the predetermined value or more, the prediction value with the latest evaluation value corresponding to the prediction value, and specifies a next prediction value after the numerical value acquisition unit acquires the command value and the evaluation value to be next treated as a latest command value and a latest evaluation value, and
does not replace, when the difference between the prediction value corresponding to the latest evaluation value and the latest evaluation value that is the specific numerical value corresponding to the prediction value is less than the predetermined value, the prediction value with the latest evaluation value corresponding to the prediction value, and specifies the next prediction value using the evaluation value after the numerical value acquisition unit acquires the command value and the evaluation value to be next treated as the latest command value and the latest evaluation value.

6. The state detection device according to claim 4, wherein the prediction value specification unit performs prediction with a learned model that has learned, as a normal state, a training command value continuously input to the machine element to operate the machine element in the normal state and a training evaluation value corresponding to the operation state of the machine element operating according to the training command value and predicts a normal value corresponding to a next training evaluation value based on a plurality of variables corresponding to the training command value and a plurality of variables corresponding to the training evaluation value, and
the prediction value specification unit specifies a prediction value corresponding to the evaluation value using, as variables, a plurality of the command values and a plurality of the evaluation values as the specific numerical value in the learned model.

7. A state detection method comprising: a numerical value acquisition step of acquiring a specific numerical value continuously detected and/or specified; and a prediction value specification step of specifying, based on a plurality of the specific numerical values acquired in the numerical value acquisition step, a prediction value of a specific numerical value next to the plurality of specific numerical values, the state detection method being for detecting a state based on the specific numerical value acquired in the numerical value acquisition step and the prediction value specified in the prediction value specification step, wherein
in the prediction value specification step,
when a difference between the specified prediction value and the specific numerical value corresponding to the prediction value is a predetermined value or more, the prediction value is replaced with the specific numerical value corresponding to the prediction value, and a next prediction value and a subsequent prediction value are specified, and
when the difference between the specified prediction value and the specific numerical value corresponding to the prediction value is less than the predetermined value, the prediction value is not replaced with the specific numerical value corresponding to the prediction value, and the next prediction value and the subsequent prediction value are specified using the specific numerical value.

8. The state detection method according to claim 7, further comprising a learned model preparation step of preparing a learned model for learning, as a normal state, a training command value continuously input to a machine element to operate the machine element in the normal state and a training evaluation value corresponding to an operation state of the machine element operating according to the training command value, and for predicting a normal value corresponding to a next training evaluation value based on a plurality of variables corresponding to the training command value and a plurality of variables corresponding to the training evaluation value, wherein
in the numerical value acquisition step, a command value continuously input to the machine element to operate the machine element and an evaluation value of the operation state of the machine element continuously detected are acquired as the specific numerical value, and
in the prediction value specification step, a prediction value corresponding to the evaluation value is specified using, as variables, a plurality of the command values and a plurality of the evaluation values as the specific numerical value in the learned model.

9. A state detection device that detects a state of a valve that changes an opening degree according to an input command signal, the state detection device comprising:
a numerical value acquisition unit that acquires, as a specific numerical value continuously detected and/or specified, information on an actual opening degree of the valve; and
a prediction value specification unit that specifies, based on the information on a plurality of the actual opening degrees acquired by the numerical value acquisition unit, a prediction value of an actual opening degree next to the plurality of actual opening degrees, wherein
the state is detected based on the information on the actual opening degree of the valve acquired by the numerical value acquisition unit and the prediction value of the actual opening degree specified by the prediction value specification unit,
the prediction value specification unit
replaces, when a difference between the specified prediction value and the actual opening degree corresponding to the prediction value is a predetermined value or more, the prediction value with the actual opening degree corresponding to the prediction value, and specifies a next prediction value and a subsequent prediction value, and
does not replace, when the difference between the specified prediction value and the actual opening degree corresponding to the prediction value is less than the predetermined value, the prediction value with the actual opening degree corresponding to the prediction value, and specifies the next prediction value and the subsequent prediction value using the actual opening degree.

10. (canceled)
